(19) United States
(12) Patent Application Publication
(10) Pub. No.: US 2025/0096496 A1
(43) Pub. Date: Mar. 20, 2025

(54) ELECTRICAL TERMINAL CONNECTOR, SUBSTRATE SUPPORT, SUBSTRATE TREATING APPARATUS

(71) Applicant: SEMES CO., LTD., Cheonan-si (KR)

(72) Inventors: Jae Oh BANG, Seoul (KR); Min Young KIM, Hwaseong-si (KR); Ju Mi LEE, Seoul (KR); Seung Hwan LEE, Cheonan-si (KR)

(21) Appl. No.: 18/803,641

(22) Filed: Aug. 13, 2024

(30) Foreign Application Priority Data
Sep. 14, 2023 (KR) 10-2023-0122513

(51) Int. Cl. H01R 13/187; H01L 21/687; H01R 13/24; H01R 107/00

(52) U.S. Cl. CPC H01R 13/187; H01L 21/68742; H01L 21/68785; H01R 13/2421; H01J 2237/002; H01R 2107/00; H01R 2201/00

(57) ABSTRACT

An electrical terminal connector, a substrate support, and a substrate processing apparatus are provided. The electrical terminal connector includes a housing unit installed by penetrating through a heater cup and having a housing ring, and a terminal connection unit installed to reciprocate within the housing unit and having a terminal connection portion to or from which an electric terminal is attached and detached. The terminal connection portion is variable so that the electric terminal is insertable when the terminal connection portion is separated from the housing ring and the electric terminal is fixed when the terminal connection portion is inserted into the housing ring together with the inserted electric terminal.

### CROSS-REFERENCE TO RELATED APPLICATIONS

This application claims benefit of priority to Korean Patent Application No. 10-2023-0122513 filed on Sep. 14, 2023 in the Korean Intellectual Property Office, the disclosure of which is incorporated herein by reference in its entirety.

### BACKGROUND

### 1. Field

The present disclosure relates to an electrical terminal connector connecting an electrical terminal and an electrical cable, a substrate support including the same, and a substrate processing apparatus.

### 2. Description of Related Art

To manufacture semiconductor devices, various processes such as photolithography, etching, deposition, ion implantation, and cleaning are performed. Thereamong, the photolithography process is a process for forming patterns and plays an important role in obtaining high integration of semiconductor devices.

The photolithography process may be largely classified as a coating process, an exposure process, and a development process, and a baking process may be performed before and after the exposure process. The baking process may be a process of heat treating a substrate. When the substrate is disposed on a heating plate, the substrate may be heat treated through a heater provided inside the heating plate.

The heating plate may be formed with an electrical terminal connected to the heater to supply electricity to the heater. Electrical cables may be assembled and electrically connected to such electric terminals, but a problem in that the electric cables may be easily disconnected from the electric terminals due to external force or high temperature may occur, resulting in disconnection.

### SUMMARY

An aspect of the present disclosure is to provide an electrical terminal connector that may easily and firmly assemble electrical terminals and electrical cables.

According to an aspect of the present disclosure, an electrical terminal connector includes a housing unit installed by penetrating through a heater cup and having a housing ring; and a terminal connection unit installed to reciprocate within the housing unit and having a terminal connection portion to or from which an electric terminal is attached and detached. The terminal connection portion is variable so that the electric terminal is insertable when the terminal connection portion is separated from the housing ring and the electric terminal is fixed when the terminal connection portion is inserted into the housing ring together with the inserted electric terminal.

The terminal connection unit may include a hollow shaft having the terminal connection portion, and the hollow shaft may include a hollow body; and the terminal connection portion disposed by penetrating through the housing ring and extending in a radial direction while extending from an end of the hollow body. The terminal connection portion may be formed of a plurality of portions spaced apart from each other, and as the plurality of portions are separated from the housing ring, a distance between the plurality of portions may gradually increase.

The terminal connection unit may further include an elastic member connecting the housing unit and the hollow shaft and applying elastic force to the hollow shaft so that the terminal connection portion moves back into the housing ring when the terminal connection portion is separated from the housing ring.

The terminal connection unit may further include a connecting pipe having one end into which an end of the hollow shaft is inserted and fastened, and the other end into which an electric cable is insertable; and a support member provided with a support hole into which the other end of the connecting pipe is inserted and fastened. The support member may be provided with a fixing groove in which the elastic member is fixed, and the hollow shaft may be connected to the elastic member by the connecting pipe and the support member.

The hollow shaft and the connecting pipe may be formed of a conductive material.

The housing unit may include a base member installed by penetrating through the heater cup and having a base hole; a screw pipe installed in the base hole and having a pipe hole; and the housing ring installed in the pipe hole.

The base member may be provided with a base entrance portion connected to the base hole, and an internal space of the base entrance portion may be tapered toward the base hole.

The housing unit may include a base body installed by penetrating through the heater cup and having a body hole; a housing installed by penetrating through the body hole, having a housing hole, and having a housing groove provided on a side to have a space spaced apart from an inner surface of the body hole; a snap ring disposed between a lower jaw of the base body and a lower jaw of the housing; a screw pipe installed in the housing hole and having a pipe hole; and the housing ring installed in the pipe hole.

The housing may have a housing inlet connected to the housing hole, and an internal space of the housing inlet may be tapered toward the housing hole.

According to an aspect of the present disclosure, a substrate support includes a heating plate equipped with a heater and an electrical terminal connected to the heater; a heater cup having a bottom portion with a support pin supporting the heating plate; and an electrical terminal connector installed on the heater cup. The electrical terminal connector includes a housing unit installed by penetrating through the heater cup and having a housing ring; and a terminal connection unit installed to reciprocate within the housing unit and having a terminal connection portion to or from which an electric terminal is attachable and detachable. The terminal connection portion has a variable structure, so that the electric terminal is insertable when the terminal connection portion is separated from the housing ring, and the electric terminal is fixed when the terminal connection portion is inserted into the housing ring together with the inserted electric terminal.

According to an aspect of the present disclosure, a substrate processing apparatus includes a processing chamber including an upper body and a lower body to form a processing space therein; a substrate support disposed in the processing space and supporting and heating a substrate; and a substrate lifting unit including a lifting pin lifted and lowered while penetrating through the substrate support, and a pin driving member lifting and lowering the lifting pin. The substrate support includes a heating plate equipped with a heater and an electrical terminal connected to the heater; a heater cup having a bottom portion with a support pin supporting the heating plate; and an electrical terminal connector installed on the heater cup. The electrical terminal connector includes a housing unit installed by penetrating through the heater cup and having a housing ring; and a terminal connection unit installed to reciprocate within the housing unit and having a terminal connection portion to and from which an electric terminal is attachable and detachable. The terminal connection portion has a variable structure, so that the electric terminal is insertable when the terminal connection portion is separated from the housing ring, and the electric terminal is fixed when the terminal connection portion is inserted into the housing ring together with the inserted electric terminal.

### BRIEF DESCRIPTION OF DRAWINGS

The above and other aspects, features, and advantages of the present disclosure will be more clearly understood from the following detailed description, taken in conjunction with the accompanying drawings, in which:

FIGS. 1 and 2 are diagrams illustrating an electric cable being connected to an electric terminal according to the related art;

FIG. 3 is a perspective view illustrating a substrate processing apparatus according to an embodiment;

FIG. 4 is a view of the substrate processing apparatus of FIG. 3 viewed from above;

FIG. 5 is a view of the substrate processing apparatus of FIG. 4 viewed in an A-A direction;

FIG. 6 is a view of the substrate processing apparatus of FIG. 4 viewed in a B-B direction;

FIG. 7 is a diagram illustrating a processing chamber including a substrate support according to an embodiment;

FIG. 8 is a view illustrating an upper portion of a substrate support according to an embodiment;

FIG. 9 is a cross-sectional view illustrating a state before a heating plate is assembled to a heater cup in the substrate support of FIG. 8;

FIG. 10 is a diagram illustrating the heater cup of FIG. 9;

FIG. 11 is a view illustrating a lower portion of the heater cup of FIG. 9;

FIG. 12 is a longitudinal cross-sectional view illustrating an electrical terminal connector installed in the heater cup of FIGS. 10 and 11;

FIGS. 13 to 16 are cross-sectional views illustrating a process in which electric terminals of a heating plate are inserted and fixed into an electrical terminal connector of a heater cup while the heating plate of FIG. 9 is assembled to the heater cup;

FIG. 17 is a diagram illustrating an electrical terminal connector according to another embodiment;

FIG. 18 is a longitudinal cross-sectional view illustrating the electrical terminal connector of FIG. 17; and

FIG. 19 is an exploded perspective view illustrating the electrical terminal connector of FIG. 17.

### DETAILED DESCRIPTION

Hereinafter, embodiments will be described in detail such that those skilled in the art may easily practice the present disclosure with reference to the accompanying drawings. However, in describing a preferred embodiment in detail, if it is determined that a detailed description of a related known function or configuration may unnecessarily obscure the gist of the present disclosure, the detailed description will be omitted. In addition, the same reference numerals are used throughout the drawings for parts having similar functions and actions. In addition, in the present specification, terms such as ‘on,’ ‘upper portion,’ ‘upper surface,’ ‘below,’ ‘lower portion,’ ‘lower surface,’ ‘side’ and the like are based on the drawings, and may be changed depending on the direction in which components are actually disposed.

In addition, throughout the specification, when a part is said to be ‘connected’ to another part, it is not only ‘directly connected,’ but also ‘indirectly connected’ with other components therebetween. Further, ‘including’ a certain component means that other components may be further included, rather than excluding other components unless otherwise stated.

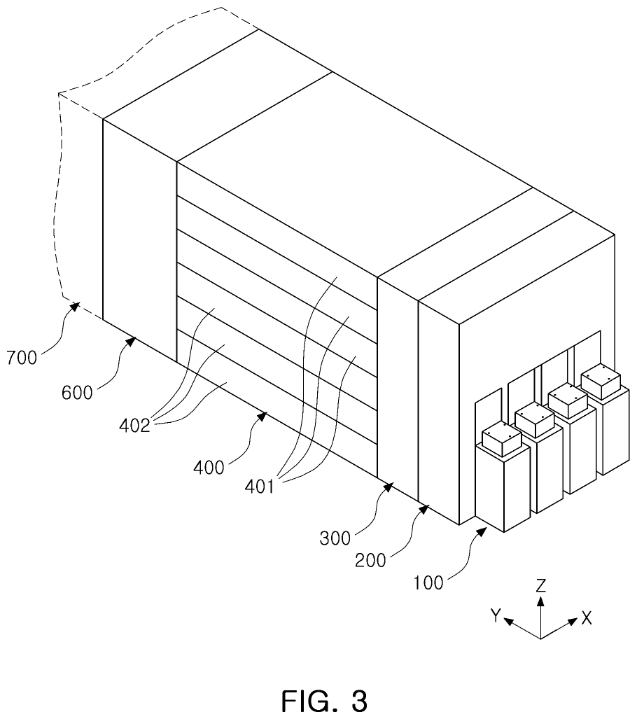

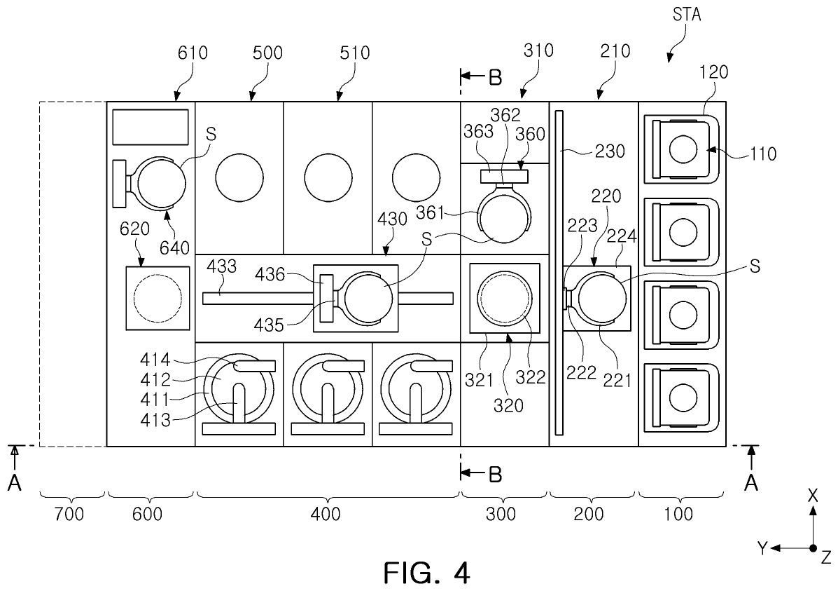

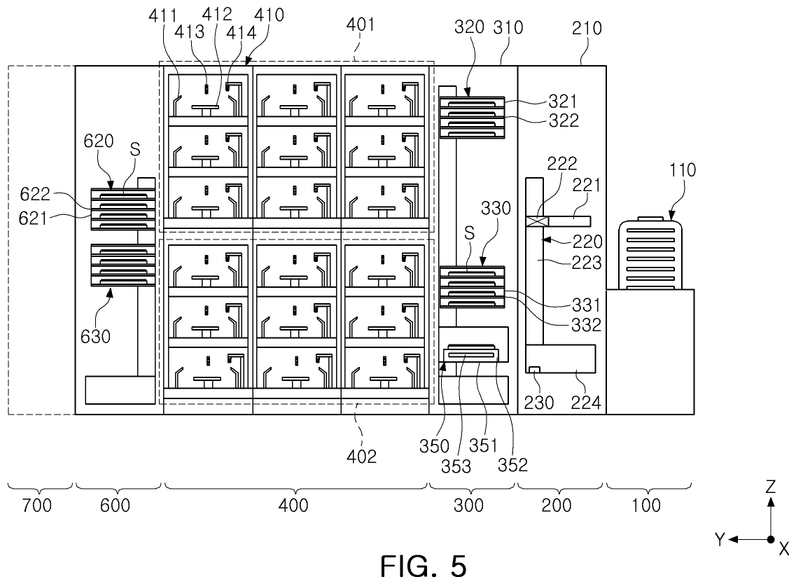

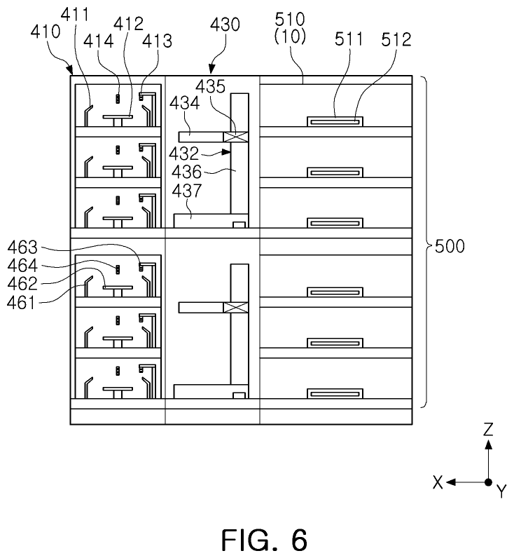

FIGS. 3 to 6 are diagrams schematically illustrating a substrate processing apparatus according to an embodiment. FIG. 3 is a perspective view illustrating a substrate processing apparatus, FIG. 4 is a view of the substrate processing apparatus of FIG. 3 viewed from the top, FIG. 5 is a view of the substrate processing apparatus of FIG. 4 viewed from the A-A direction, and FIG. 6 is a view of the substrate processing apparatus of FIG. 4 viewed from the B-B direction.

Referring to FIGS. 3 to 6, a substrate processing apparatus STA includes a load port 100, an index module 200, a buffer module 300, an application and development module 400, and a purge module 800. The load port 100, the index module 200, the buffer module 300, the application and development module 400, and the interface module 600 are sequentially arranged in one direction.

Hereinafter, the direction in which the load port 100, index module 200, buffer module 300, application and development module 400, and interface module 600 are arranged is referred to as the first direction (Y), and when viewed from the top, the direction perpendicular to the first direction (Y) is referred to the second direction (X), and respectively perpendicular to the first a direction direction (Y) and the second direction (X) is referred to the third direction (Z).

A substrate S is moved while stored in a cassette 110. The cassette 110 has a structure that may be sealed from the outside. As an example, a Front Open Unified Pod (FOUP) having a door at the front may be used as the cassette 110.

Below, the load port 100, the index module 200, the buffer module 300, the application and development module 400, and the interface module 600 will be described in detail.

The load port 100 has a susceptor 120 on which the cassette 110 containing the substrate S is placed. A plurality of susceptors 120 are provided, and the susceptors 120 are arranged in a row along the second direction (X). In FIG. 4, an example in which four susceptors 120 are provided is illustrated, but the number may be changed.

The index module 200 transfers the substrate S between the cassette 110 disposed on the susceptor 120 of the load port 100 and the buffer module 300. The index module 200 includes a frame 210, an index robot 220, and a guide rail 230. The frame 210 is generally provided in the shape of a rectangular parallelepiped with an empty interior, and is disposed between the load port 100 and the buffer module 300. The frame 210 of the index module 200 may be provided at a lower height than the frame 310 of the buffer module 300. The index robot 220 and the guide rail 230 are disposed within the frame 210. The index robot 220 is provided so that the hand 221, which directly handles the substrate S, may move and rotate in the first direction (Y), the second direction (X), and the third direction (Z). The index robot 220 includes a hand 221, an arm 222, a support 223, and a pedestal 224. The hand 221 is fixedly installed on the arm 222. The arm 222 is provided in a stretchable structure and a rotatable structure. The support 223 is disposed so that the longitudinal direction thereof is provided as the third direction (Z). The arm 222 is coupled to the support 223 to be movable along the support 223. The support 223 is fixedly coupled to the pedestal 224. The guide rail 230 is provided so that the longitudinal direction is disposed along the second direction (X). The pedestal 224 is coupled to the guide rail 230 so that it may move linearly along the guide rail 230. In addition, although not illustrated, the frame 210 is further provided with a door opener that opens and closes the door of the cassette 110.

The buffer module 300 includes a frame 310, a first buffer 320, a second buffer 330, a cooling chamber 350, and a first buffer robot 360. The frame 310 is provided in the shape of a rectangular parallelepiped with an empty interior, and is disposed between the index module 200 and the application and development module 400. The first buffer 320, the second buffer 330, the cooling chamber 350, and the first buffer robot 360 are located within the frame 310. The cooling chamber 350, the second buffer 330, and the first buffer 320 are sequentially arranged from below along the third direction (Z). The first buffer 320 is located at a height corresponding to an application module 401 of the application and development module 400, and the second buffer 330 and the cooling chamber 350 are provided at a height corresponding to the developing module 402 of the coating and development module 400. The first buffer robot 360 is positioned at a certain distance from the second buffer 330, the cooling chamber 350, and the first buffer 320 in the second direction (X). The first buffer 320 and the second buffer 330 each temporarily store a plurality of substrates S. The second buffer 330 has a housing 331 and a plurality of supports 332. The supports 332 are disposed within the housing 331 and are spaced apart from each other along the third direction (Z). One substrate S is disposed on each support 332. The housing 331 has an opening in the direction in which the index robot 220 is provided and in the direction in which the first buffer robot 360 is provided, so that the index robot 220 and the first buffer robot 360 may load or unload the substrate S into or out of the support 332 within the housing 331. The first buffer 320 has a generally similar structure to the second buffer 330. However, the housing 321 of the first buffer 320 has an opening in the direction in which the first buffer robot 360 is provided and in the direction in which an applicator robot 432 located in the applicator module 401 is provided. The number of supports 322 provided in the first buffer 320 and the number of supports 332 provided in the second buffer 330 may be the same or different. According to an example, the number of supports 332 provided in the second buffer 330 may be greater than the number of supports 322 provided in the first buffer 320.

The first buffer robot 360 transfers the substrate S between the first buffer 320 and the second buffer 330 as illustrated in FIG. 4. The first buffer robot 360 includes a hand 361, an arm 362, and a support 363. The hand 361 is fixedly installed on the arm 362. The arm 362 is provided in a stretchable structure so that the hand 361 may move along the second direction (X). The arm 362 is coupled to the support 363 to be able to move linearly in the third direction (Z) along the support 363. The support 363 has a length extending from a position corresponding to the second buffer 330 to a position corresponding to the first buffer 320, and the support 363 may be provided longer than this length in the upper or lower direction. The first buffer robot 360 may be provided so that the hand 361 is driven only in two axes along the second direction (X) and the third direction (Z).

The cooling chambers 350 cool the substrates S, respectively, as illustrated in FIG. 5. The cooling chamber 350 includes a housing 351 and a cooling plate 352. The cooling plate 352 has an upper surface on which the substrate S is disposed and a cooling unit 353 for cooling the substrates S. In the cooling unit 353, various methods may be used, such as cooling using coolant or cooling using thermoelectric elements. Additionally, the cooling chamber 350 may be provided with a lift pin assembly for positioning the substrate S on the cooling plate 352. The housing 351 has an opening in the direction in which the index robot 220 is provided and in the direction in which the developer robot is provided, so that the index robot 220 and the developer robot provided in the developing module 402 may load or unload the substrate S into or out of the cooling plate 352. Additionally, the cooling chamber 350 may be provided with doors that open and close the above-mentioned openings.

The application module 401 includes a process of applying a photosensitive liquid such as photoresist to the substrate S and a heat treatment process such as heating and cooling to the substrate S before and after the resist application process. The application module 401 has an application chamber 410, a baking chamber unit 500, and a transfer chamber 430. The application chamber 410, the transfer chamber 430, and the baking chamber unit 500 are sequentially arranged along the second direction (X). For example, based on the transfer chamber 430, the application chamber 410 is provided on one side of the transfer chamber 430, and the baking chamber unit 500 is provided on the other side of the transfer chamber 430.

A plurality of application chambers 410 may be provided, and the plurality of application chambers 410 are provided in each of the first direction (Y) and the third direction (Z). The baking chamber unit 500 includes a plurality of baking chambers 510, and the plurality of baking chambers 510 are provided in each of the first direction (Y) and the third direction (Z). The transfer chamber 430 is located parallel to the first buffer 320 of the first buffer module 300 in the first direction (Y). The applicator robot 432 and a guide rail 433 are located within the transfer chamber 430. The transfer chamber 430 has a generally rectangular shape. The applicator robot 432 transfers the substrate S between the baking chamber 510, the applicator chamber 410, and the first buffer 320 of the first buffer module 300.

The guide rail 433 is disposed so that the longitudinal direction thereof is parallel to the first direction (Y). The guide rail 433 guides the applicator robot 432 to move straight in the first direction (Y). The applicator robot 432 has a hand 434, an arm 435, a support 436, and a pedestal 437 as illustrated in FIG. 6. The hand 434 is fixedly installed on the arm 435. The arm 435 is provided in a stretchable structure so that the hand 434 may move in the horizontal direction. The support 436 is provided so that the longitudinal direction thereof is disposed along the third direction (Z). The arm 435 is coupled to the support 436 to be able to move linearly in the third direction (Z) along the support 436. The support 436 is fixedly coupled to the pedestal 437, and the pedestal 437 is coupled to the guide rail 433 to be movable along the guide rail 433.

All of the application chambers 410 may have the same structure, but the types of chemical solutions used in respective application chambers 410 may be different. As a chemical solution, a chemical solution for forming a photoresist film or an anti-reflection film may be used.

The application chamber 410 applies the chemical solution on the substrate S. The application chamber 410 has a cup 411, a substrate support 412, and a nozzle 413. The cup 411 has an open top. The substrate support 412 is located within the cup 411 and supports the substrate S. The substrate support 412 is provided to be rotatable. The nozzle 413 supplies a chemical solution onto the substrate S disposed on the substrate support 412. The chemical solution is applied to the substrate S using a spin coating method. Additionally, in the application chamber 410, a nozzle 414 that supplies a cleaning solution such as deionized water (DIW) to clean the surface of the substrate S on which the chemical solution is applied, and a back rinse nozzle (not illustrated) for cleaning the lower surface of the substrate S, may be further provided.

The baking chamber 510 is equipped with a substrate support 511 and a heater 512 built into the substrate support 511 in the internal processing space, and when the substrate S is disposed on the substrate support 511, the applicator robot 432 heat-treats the substrate S. For example, the baking chamber 510 performs a prebaking process in which organic matter or moisture on the surface of the substrate S is removed by heating the substrate S to a predetermined temperature before applying photoresist, a soft baking process performed after applying photoresist on the substrate S, or the like, and performs a cooling process to cool the substrate S after each heating process, and the like.

The interface module 600 connects the application and development module 400 with an external exposure apparatus 700. The interface module 600 includes an interface frame 610, a first interface buffer 620, a second interface buffer 630, and a transfer robot 640, and the transfer robot 640 transfers the substrate having returned to the first and second interface buffers 620 and 630 after the application and development module 400 is completed, to the exposure apparatus 700. The first and second interface buffers 620 and 630 include a housing 621 and a support 622, and the transfer robot 640 and the applicator robot 432 load/unload the substrate S into and out of the support 622.

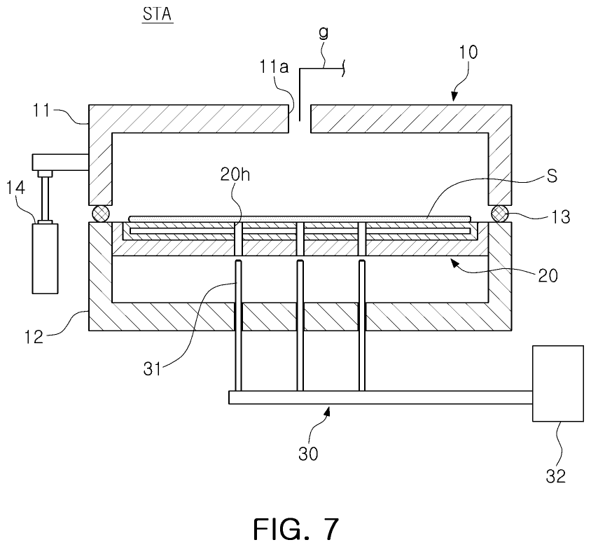

FIG. 7 is a diagram illustrating a processing chamber including a substrate support according to an embodiment.

Referring to the drawings, the substrate processing apparatus STA according to an embodiment of the present disclosure may include a processing chamber 10, a substrate support 20, and a substrate lifting unit 30.

The processing chamber 10 has a processing space therein, in which the substrate S is heat-processed. The processing chamber 10 may include an upper body 10a and a lower body 10b to form a processing space. A sealing member 13 may be installed on one of the upper body 11 and the lower body 12, and a body lifting member 14 may be installed on the upper body 11. A gas supply line g is connected to an upper hole 11a of the upper body 11 so that gas may be supplied to the substrate S. Gas may be supplied to the processing space during heating of the substrate S to improve the adhesion rate of the photoresist (photosensitive liquid) to the substrate. This processing chamber 10 may be the above-described baking chamber (510 in FIG. 6), and is not limited by the above description and may be used in any process for heating a substrate.

Additionally, the substrate support 20 is disposed in the processing space and supports and heats the substrate S, which will be described later.

The substrate lifting unit 30 may include a lifting pin 31 and a pin driving member 32. The lifting pin is lifted while penetrating the substrate support 20 through the pinhole 20h of the substrate support 20, and the pin driving member 32 is connected to the lifting pin 31 to raise and lower the lifting pin 31. The lifting pin 31 supports the substrate S when raised by the pin driving member 32 and raises the substrate S.

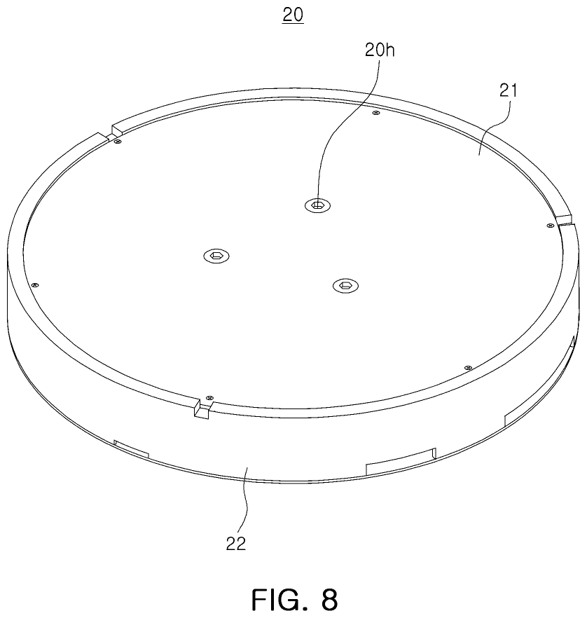

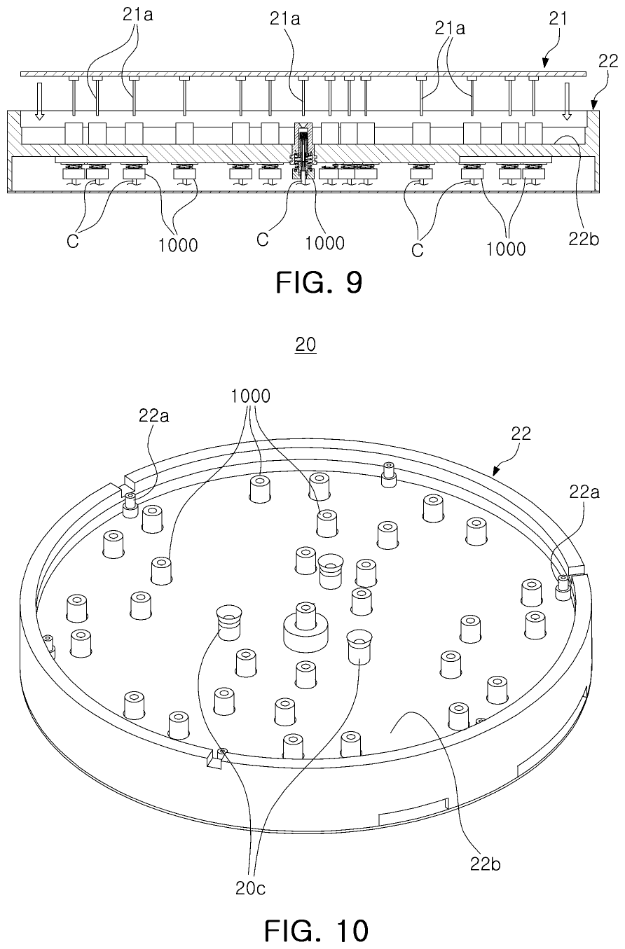

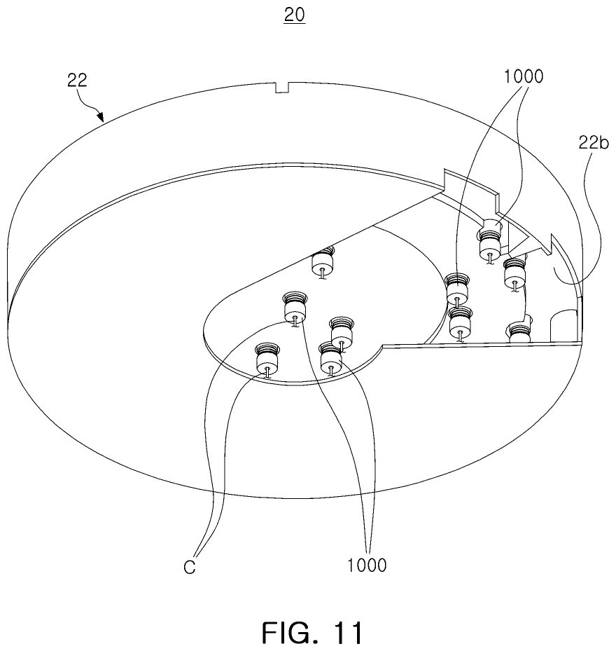

FIG. 8 is a view illustrating the upper portion of the substrate support according to an embodiment, FIG. 9 is a cross-sectional view illustrating the state before the heating plate is assembled to the heater cup in the substrate support of FIG. 8, FIG. 10 is a view illustrating the heater cup of FIG. 9, and FIG. 11 is a view illustrating the lower portion of the heater cup of FIG. 9.

Referring to the drawings, the substrate support 20 may include a heating plate 21, a heater cup 22, and an electrical terminal connector 1000.

The heating plate 21 has a circular plate shape and a substrate is mounted on the upper surface thereof. Additionally, the heating plate 21 is equipped with a heater (not illustrated) and an electric terminal 21a to heat the seated substrate. The heater is installed inside the heating plate 21 and may be a heating wire or thermoelectric element. A plurality of the heaters may be provided in a concentric circle shape, and an electric terminal 21a may be installed on an end of each of the plurality of heaters. For example, a plurality of electrical terminals 21a may be installed and fixed to the heating plate 21. Furthermore, a pinhole 20h may be formed in the heating plate 21.

Additionally, the heater cup 22 is formed with a bottom portion 22b having a support pin 22a supporting the heating plate 21. The heater cup 22 has a structure that supports and surrounds the heating plate 21, and the support pin 22a is installed on the upper portion of the bottom portion 22b. In addition, a hole cylinder 20c may be installed by penetrating through the bottom portion 22b to communicate with the pinhole 20h of the heating plate 21.

The electrical terminal connector 1000 is installed in the heater cup 22. The electrical terminal connector 1000 serves to connect the electrical terminal 21a of the heating plate 21 and the electrical cable C, and as a result, electricity received from the electric cable C may be supplied to the heater through the electric terminal 21a.

Prior to a detailed description of the electrical terminal connector 1000 according to an embodiment of the present disclosure, the structure of connecting an electrical cable to the electrical terminal of a heating plate in the related art is as follows.

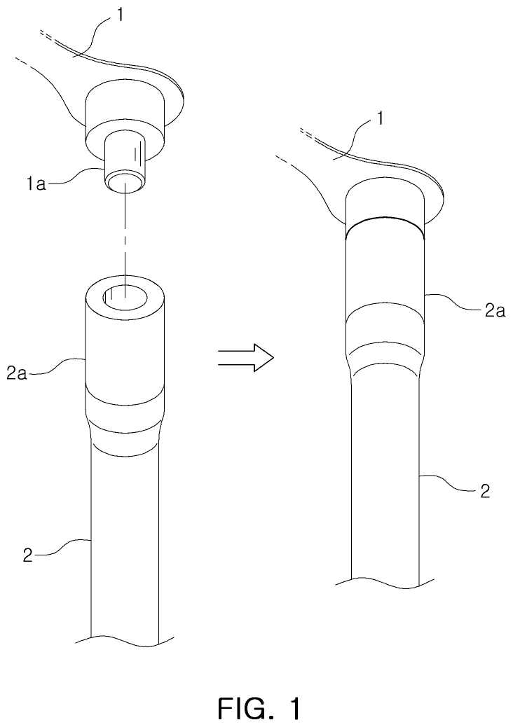

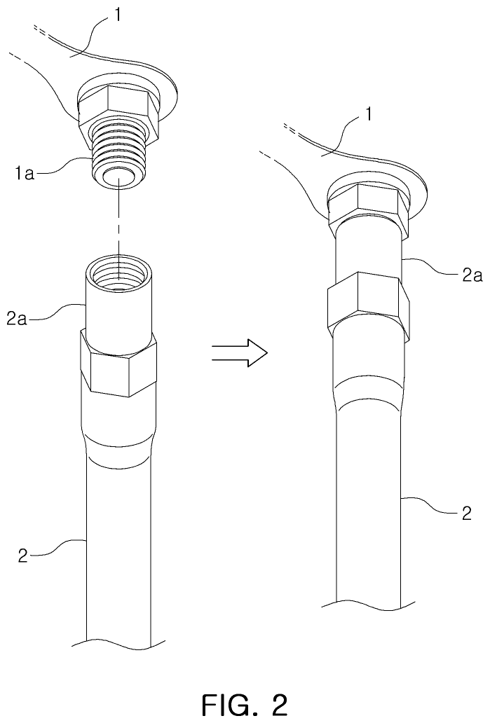

FIGS. 1 and 2 are diagrams illustrating an electric cable being connected to an electric terminal according to the related art.

Referring to the drawing, an electric terminal 1a installed on a heating wire 1 of a heating plate is formed to protrude downward from the lower surface of the heating plate 21. To be connected to the electric terminal 1a, a cable terminal 2a is formed on the end of the electric cable 2.

In detail, referring to FIG. 1, the cable terminal 2a has a female terminal structure with an assembly hole formed, and the electric terminal 1a has a male terminal structure formed to be inserted into the assembly hole. To connect the electric cable 2 to the electric terminal 1a of this structure, the electric terminal 1a is forcibly inserted into the assembly hole of the cable terminal 2a and assembled.

Also, referring to FIG. 2, the cable terminal 2a has a female terminal structure with an assembly hole, and has a thread line formed on the inner peripheral surface, and the electrical terminal 1a has a male terminal structure formed to be inserted into an assembly hole, and has a thread line formed on the outer peripheral surface. To connect the electric terminal 1a and the electric cable 2 having this structure to each other, the electric terminal 1a is inserted into the assembly hole of the cable terminal 2a and assembled while the cable terminal 2a is screwed and rotated.

However, the assembly structure according to the related art disclosed in FIGS. 1 and 2 has a problem in that the electric cable 2 is easily separated from the electric terminal 1a due to external force or high temperature, which causes disconnection.

To prevent the problems described above, the electrical terminal connector according to an embodiment of the present disclosure is configured as follows.

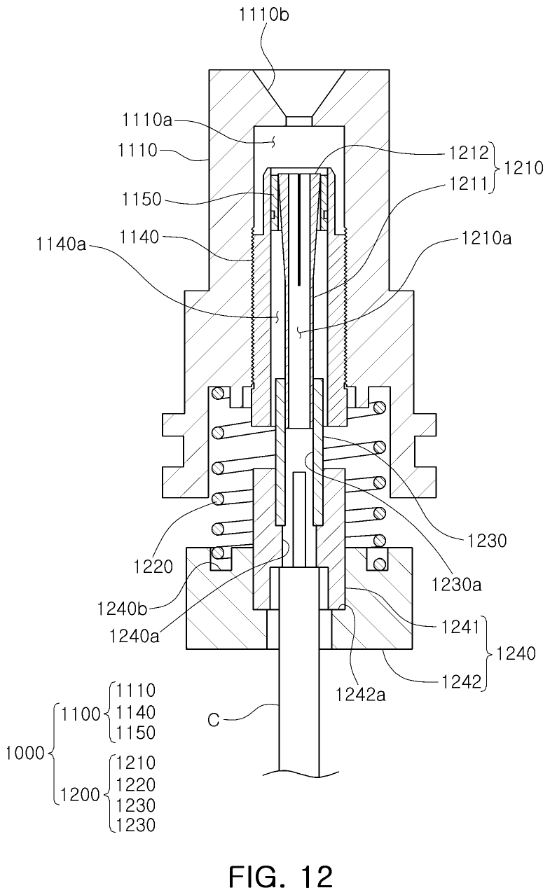

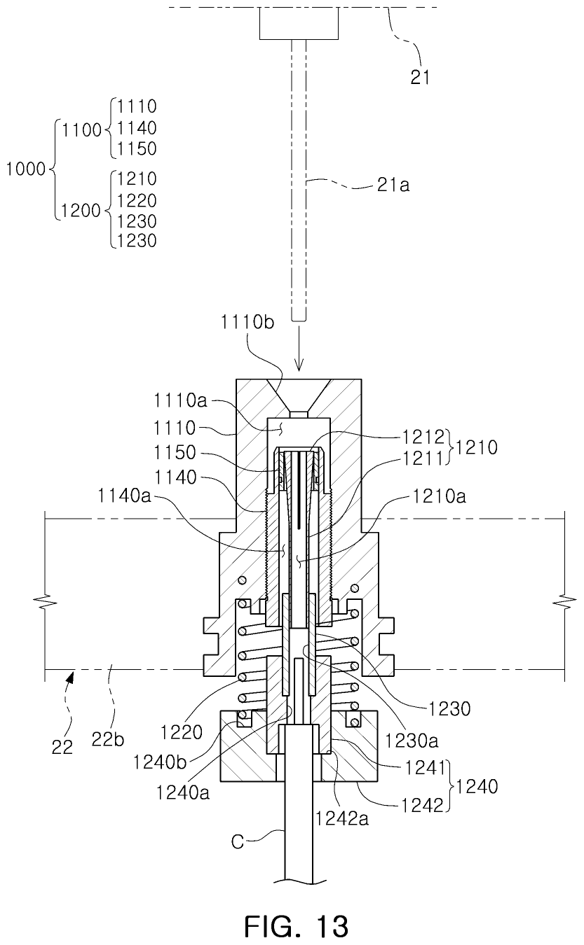

FIG. 12 is a longitudinal cross-sectional view illustrating the electrical terminal connector installed on the heater cup of FIGS. 10 and 11, and FIGS. 13 to 16 are cross-sectional views illustrating the process in which the electric terminals of the heating plate are inserted and fixed into the electrical terminal connector of the heater cup while the heating plate of FIG. 9 is assembled to the heater cup.

Referring to the drawing, the housing unit 1100 of the electrical terminal connector 1000 according to an embodiment is installed by penetrating through the heater cup 22 and has a housing ring 1150.

In addition, the terminal connection unit 1200 is installed to reciprocate within the housing unit 1100, the electrical terminal 21a is attached to and detached from an upper portion of the terminal connection unit 1200, and an electric cable C may be inserted into and fixed to the lower portion thereof.

The terminal connection unit 1200 is formed with a terminal connection portion 1212 to and from which the electric terminal 21a is attached and detachable.

In this case, the terminal connection portion 1212 is varied so that, when separated from the housing ring 1150, the electrical terminal 21a may be inserted, and when inserted into the housing ring 1150 together with the inserted electrical terminal 21a, the electrical terminal 21a may be fixed.

To examine the variable structure of the terminal connection portion 1212 described above, the configuration of the terminal connection unit 1200 is examined in detail as follows.

The terminal connection unit 1200 may include a hollow shaft 1210 having the terminal connection portion 1212.

The hollow shaft 1210 has a shaft structure in which a hollow 1210a is formed along the longitudinal direction. At this time, the hollow 1210a is the part where the electric terminal 21a is inserted.

The hollow shaft 1210 may include a hollow body 1211 and the terminal connection portion 1212.

The terminal connection portion 1212 extends from the end of the hollow body 1211. In the drawing, the hollow body 1211 is located on the lower portion, and the terminal connection portion 1212 is located on the upper portion. In this manner, as the terminal connection portion 1212 has a structure extending from the hollow body 1211, the hollow 1210a is formed along the inside of the hollow body 1211 and the terminal connection portion 1212.

The terminal connection portion 1212 is disposed by penetrating through the housing ring 1150, and for example, has a structure inserted into the housing ring 1150. In addition, the terminal connection portion 1212 extends from the hollow body 1211 and is formed to expand in the radial direction. In detail, the terminal connection portion 1212 may have a shape that expands in the radial direction toward the top.

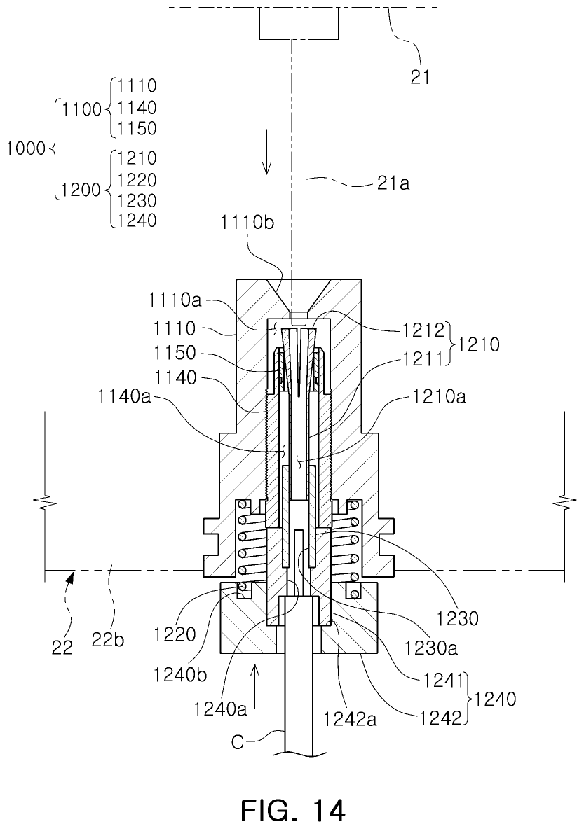

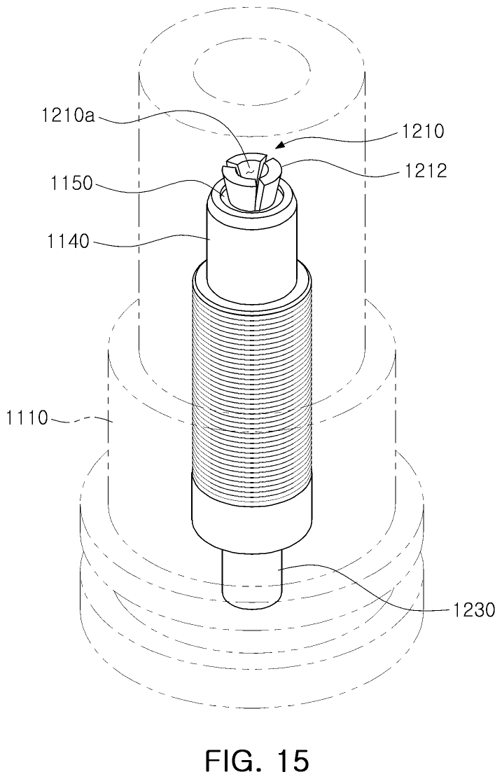

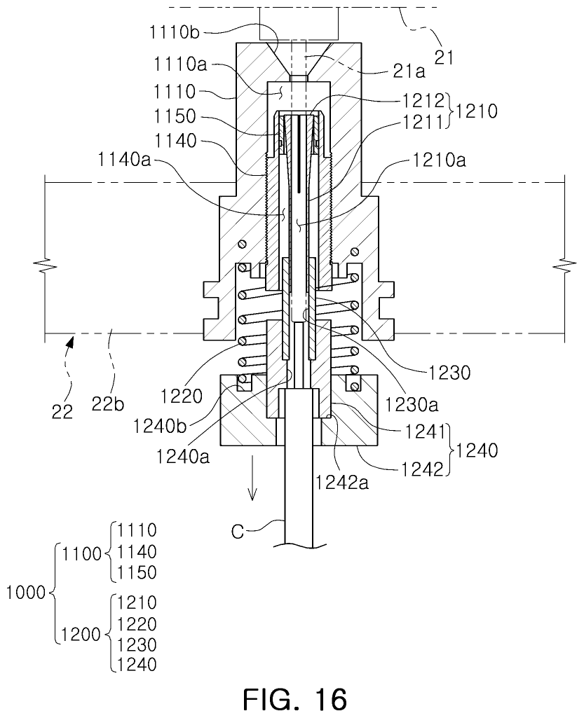

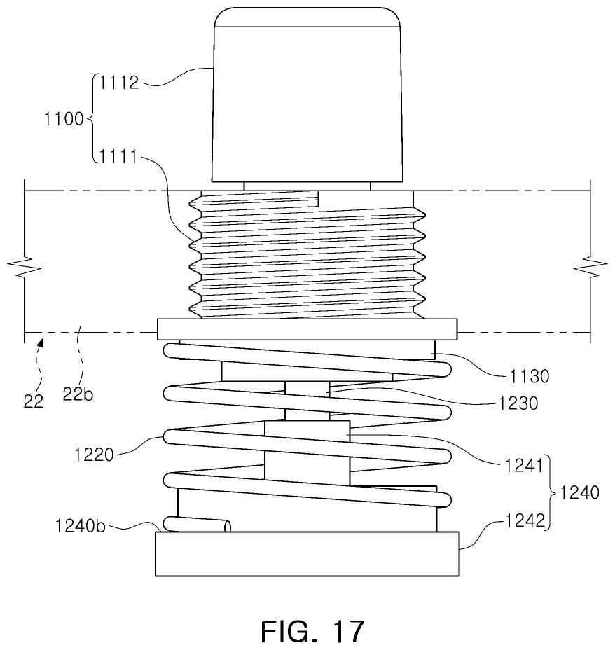

In more detail, the terminal connection portion 1212 may be composed of a plurality of portions. A plurality of portions have a structure surrounding the hollow 1210a. As these plural portions separate from the housing ring 1150, the distance between the plurality of portions gradually becomes distant. For example, the plurality of portions are formed so that the lower ends thereof extend upward from the hollow body 1211, and as illustrated in FIGS. 14 and 15, when the plurality of portions move upward and separate from the housing ring 1150, the pressure caused by the housing ring 1150 is released, thereby increasing the distance between the plurality of portions. In detail, the plurality of portions have a shape that spreads upwards when the plurality of portions are not inserted into the housing ring 1150, and as illustrated in FIG. 16, the plurality of portions have an inwardly collapsed shape when the plurality of portions are inserted into the housing ring 1150 and pressed by the housing ring 1150.

The terminal connection portion 1212 configured as described above allows the electrical terminal 21a to be inserted when separated from the housing ring 1150, as illustrated in FIGS. 14 and 15. For example, the plurality of portions move upward and separate from the housing ring 1150, so that the distance therebetween becomes greater toward the upper side. As a result, the vertical hollow 1210a surrounded by the plurality of portions becomes larger in diameter toward the top, allowing the electrical terminal 21a to be easily inserted.

Furthermore, on the contrary, as illustrated in FIG. 16, the terminal connection portion 1212 fixes the electrical terminal 21a when inserted into the housing ring 1150 together with the electrical terminal 21a inserted. For example, the plurality of portions moves downward and moves inside the housing ring 1150, thereby reducing the gap therebetween. As a result, hollow 1210a surrounded by a plurality of portions becomes smaller in diameter, thereby pressing the electrical terminal 21a and fixing the electrical terminal 21a.

On the other hand, the terminal connection unit 1200 may further include an elastic member 1220, as illustrated in FIGS. 12 to 16.

The elastic member 1220 connects the housing unit 1100 and the hollow shaft 1210, and when the terminal connection portion 1212 is separated from the housing ring 1150, an elastic force is applied to the hollow shaft 1210 so that the terminal connection portion 1212 moves back into the housing ring 1150. For example, the hollow shaft 1210 is connected to the housing unit 1100 fixed to the heater cup 22 by the elastic member 1220, and is pulled by the elastic force of the elastic member 1220, moves down, and moves back into the housing ring 1150 when the hollow shaft 1210 rises upward to separate from the housing ring 1150 of the housing unit 1100. At this time, the connection structure of the elastic member 1220 to the housing unit 1100 and the hollow shaft 1210 includes not only a direct connection structure but also an indirect connection structure.

As a detailed example of the indirect connection structure, the terminal connection unit 1200 may further include a connecting pipe 1230 and a support member 1240.

The connecting pipe 1230 has a structure in which the end of the hollow shaft 1210 is inserted and fastened to one end and an electric cable C may be inserted into the other end. For example, the connecting pipe 1230 has a pipe hole 1230a formed therein, and the lower end of the hollow shaft 1210 is inserted into and fastened to the upper end of the connecting pipe, and an electric cable C may be inserted into the lower end thereof. In this manner, with the electric cable C inserted into the lower portion of the connecting pipe 1230, by inserting the electrical terminal 21a into the connecting pipe 1230 through the hollow shaft 1210, the electrical terminal 21a and the electrical cable C may be contacted and electrically connected to each other. The hollow shaft 1210 and the connecting pipe 1230 may be formed of a conductive material. As a result, the electrical terminal 21a and the electrical cable C may be electrically connected through the hollow shaft 1210 and the connecting pipe 1230 without direct contact therebetween.

In addition, the support member 1240 may be formed with a support hole 1240a into which the other end of the connecting pipe 1230 is inserted and fastened. A fixing groove 1240b to which the elastic member 1220 is fixed may be formed in the support member 1240, and the hollow shaft 1210 may be connected to the elastic member 1220 by the connecting pipe 1230 and the support member 1240. As a detailed example, the support member 1240 may be composed of a sleeve 1241 and a pusher 1242 assembled together. The support hole 1240a is formed in the sleeve 1241, the fixing groove 1240b is formed in the pusher 1242, and an assembly hole 1242a may be formed in the pusher 1242 into which the lower portion of the sleeve 1241 is screwed.

As illustrated in FIGS. 14 and 15, when an external force is applied upward to the pusher 1242 of the support member 1240 described above, as the sleeve 1241 and the hollow shaft 1210 are pushed up together with the pusher 1242, the terminal connection portion 1212 of the hollow shaft 1210 rises and separates from the housing ring 1150, and the electrical terminal 21a may be inserted into the terminal connection portion 1212. In this manner, when the electric terminal 21a is inserted into the terminal connection portion 1212 and the external force applied to the pusher 1242 disappears as illustrated in FIG. 16, as the sleeve 1241 and the hollow shaft 1210 are pushed down together with the pusher 1242 by the elastic force of the elastic member 1220, the terminal connection portion 1212 of the hollow shaft 1210 is lowered and re-entered into the housing ring 1150, and thus, the electrical terminal 21a is fixed to the terminal connection portion 1212.

A separate jig (not illustrated) may be used to apply external force to the pusher 1242 as described above. A plurality of pressing portions are formed in the jig, so that pressure may be applied simultaneously to the plurality of pushers 1242 formed on the plurality of electrical terminal connectors 1000.

Meanwhile, as an example, the housing unit 1100 may include a base member 1110, a screw pipe 1140, and a housing ring 1150.

The base member 1110 is installed by penetrating through the bottom portion 22b of the heater cup 22, and for example, may be installed by screwing. The base member 1110 may have a base hole 1110a formed in the longitudinal direction. Furthermore, a base entrance portion 1110b connected to the base hole 1110a is formed in the base member 1110, and the internal space of the base entrance portion 1110b may be tapered toward the base hole 1110a. The base entrance portion 1110b formed in a tapered manner may guide the electrical terminal 21a of the heating plate 21 to be inserted into the base hole 1110a.

Additionally, the screw pipe 1140 is installed in the base hole 1110a, and may be installed by screwing as an example. The screw pipe 1140 may have a pipe hole 1140a formed in the longitudinal direction.

In addition, the housing ring 1150 is installed and fixed in the pipe hole 1140a, and in detail, may be disposed in an upper portion inside the pipe hole 1140a. The housing ring 1150 has a ring shape and has a structure that surrounds and presses the terminal connection portion 1212 disposed therein.

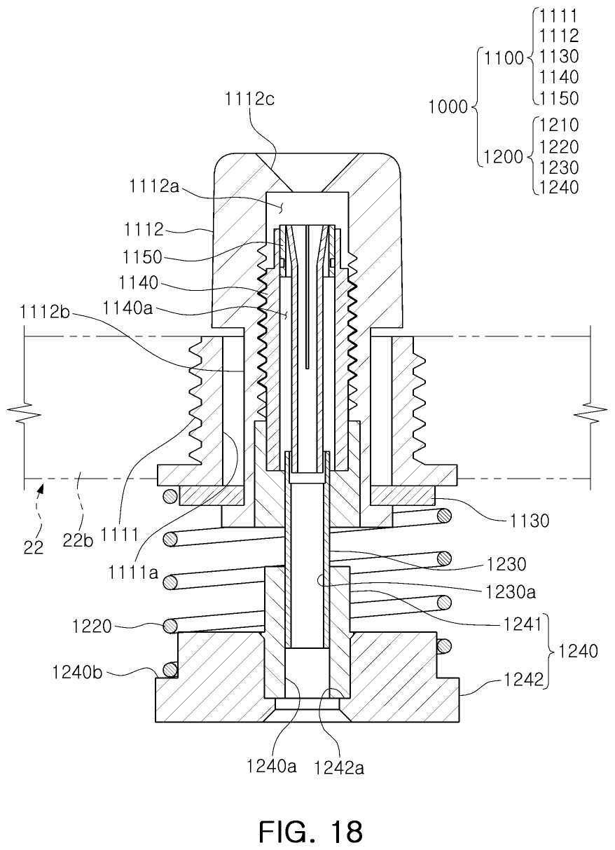

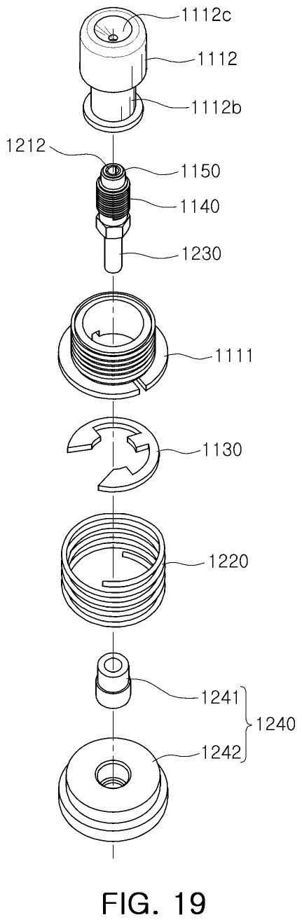

FIG. 17 is a diagram illustrating an electrical terminal connector according to another embodiment, FIG. 18 is a longitudinal cross-sectional view illustrating the electrical terminal connector of FIG. 17, and FIG. 19 is an exploded perspective view illustrating the electrical terminal connector of FIG. 17.

Referring to the drawings, the housing unit 1100 according to another embodiment may include a base body 1111, a housing 1112, a snap ring 1130, a screw pipe 1140, and a housing ring 1150.

The base body 1111 may be installed by penetrating through the heater cup 22 and may have a body hole 1111a.

Additionally, the housing 1112 may be installed by penetrating through the body hole 1111a and may have a housing hole 1112a formed therein. In this housing 1112, even if there is a slight difference in position between the plurality of electrical terminals 21a and the plurality of electrical terminal connectors 1000, the side of the housing 1112 may be spaced at an appropriate distance from the inner surface of the body hole 1111a, thereby resolving this difference. A plurality of electrical terminals 21a are installed on the heater plate, and a plurality of electrical terminal connectors 1000 are installed on the heater cup 22 to correspond thereto. The plurality of electrical terminal connectors 1000 should be located on the heater cup 22 to correspond to the positions of the plurality of electrical terminals 21a, and in this case, some of the plurality of electrical terminal connectors 1000 may have slight differences in position from the electrical terminals 21a corresponding. The housing 1112 may have a housing groove 1112b formed on the side to have a space separated from the inner surface of the body hole 1111a, so that despite these positional differences, the plurality of electrical terminals 21a may be smoothly and firmly connected to the plurality of electrical terminal connectors 1000. For example, the housing 1112 is installed by penetrating through the body hole 1111a, and the housing groove 1112b is formed along the outer peripheral surface, so that the housing 1112 may be disposed at an appropriate distance from the inner surface of the body hole 1111a. By adopting this structure, the housing 1112 may move laterally to a certain extent within the body hole 1111a, and the terminal connection unit 1200 to which the electrical terminal 21a is attached and detachable may also be moved. Therefore, even if the positions of the electrical terminal 21a and the electrical terminal connector 1000 corresponding to each other are slightly different, by moving the terminal connection unit 1200 of the electrical terminal connector 1000 to the corresponding position of the electrical terminal 21a, the electrical terminal 21a corresponding and electrical terminal connector 1000 may be connected smoothly and firmly.

Furthermore, a housing inlet 1112c connected to the housing hole 1112a is formed in the house body, and the internal space of the housing inlet 1112c may be tapered toward the housing hole 1112a. The housing inlet 1112c, which is formed to be tapered in this manner, may guide the electrical terminal 21a of the heating plate 21 into the housing hole 1112a.

In addition, the snap ring 1130 may be disposed between the lower jaw of the base body 1111 and the lower jaw of the housing 1112. The snap ring 1130 is inserted between the lower jaw of the base body 1111 and the lower jaw of the housing 1112, thereby preventing separation of the housing 1112.

The screw pipe 1140 is installed in the housing hole 1112a, an as an example, may be installed by screwing. The screw pipe 1140 may have a pipe hole 1140a formed in the longitudinal direction.

Additionally, the housing ring 1150 is installed and fixed in the pipe hole 1140a, and in detail, may be disposed in an upper portion inside the pipe hole 1140a. The housing ring 1150 has a ring shape and has a structure that surrounds and presses the terminal connection portion 1212 disposed therein.

In addition, among the components not described in FIGS. 17 to 19, the components having the same reference numerals as the components illustrated in FIGS. 12 to 16 have the same structure, and thus, description thereof will be omitted.

As a result, the electrical terminal connector 1000 according to an embodiment of the present disclosure has a terminal connection portion 1212 with a variable structure, thereby reducing the number of assembly man-hours for the electrical cable C to the electrical terminal 21a, and furthermore, the electrical terminal 21a and the electrical cable C may be firmly assembled. In detail, in the present disclosure, when the terminal connection portion 1212 is separated from the housing ring 1150, the electric terminal 21a is configured to be inserted into the terminal connection portion 1212, and when the terminal connection portion 1212 is inserted into the housing ring 1150 together with the electrical terminal 21a, a structure that secures the electrical terminal 21a may be obtained. Therefore, in the present disclosure, the electrical terminal 21a may be easily inserted and fixed into the terminal connection portion 1212, thereby reducing the number of hours of assembly of the electrical cable C for the electrical terminal 21a, and in addition, the electrical terminal 21a and the electrical cable C may be firmly assembled.

Furthermore, the electrical terminal connector 1000 according to an embodiment of the present disclosure is installed by penetrating through the heater cup 22, and therefore, a plurality of electric cables C may be prevented from being complicatedly disposed in the space between the heating plate 21 and the heater cup 22, and thus, during forced cooling, cooling may be obtained well and uniformly. In detail, as an example during the baking process, forced cooling may be performed to lower the temperature from 120° C. to 90° C. For this cooling, cooling air may be supplied between the bottom portion 22b of the heater cup 22 and the heating plate 21. However, in the related art, the electric cable C is directly connected to the electric terminal 21a of the heating plate 21, and thus, many electric cables C are disposed complexly and irregularly between the heating plate 21 and the bottom portion 22b of the heater cup 22, and in the supply of cooling air, there is also a limitation in that cooling is not performed well and is not performed uniformly due to the interference of a large number of electric cables C. In contrast, the present disclosure adopts a structure in which the electric terminal 21a and the electric cable C are connected by the electrical terminal connector 1000 disposed by penetrating through the heater cup 22. Therefore, in the present disclosure, as illustrated in FIGS. 9 to 11, as a large number of electric cables C are disposed below the bottom portion 22b of the heater cup 22 rather than between the heating plate 21 and the bottom portion 22b of the heater cup 22, and during forced cooling, cooling may be obtained well and evenly.

As set forth above, according to an embodiment, as a terminal connection portion having a variable structure is configured, the number of hours of assembly of electric cables to electric terminals may be reduced, and an effect of firmly assembling electric terminals and electric cables may also be obtained.

Furthermore, in an embodiment, electric terminals and electric cables are connected through electrical terminal connectors disposed by penetrating through a heater cup, and thus, a relatively large number of electric cables are disposed below the bottom portion of the heater cup rather than between the heating plate and the bottom portion of the heater cup. Accordingly, cooling occurs well during forced cooling, and additionally, it has the advantage of allowing uniform cooling.

While example embodiments have been illustrated and described above, it will be apparent to those skilled in the art that modifications and variations could be made without departing from the scope of the present disclosure as defined by the appended claims.

What is claimed is:

1. An electrical terminal connector comprising:
a housing unit installed by penetrating through a heater cup and having a housing ring; and
a terminal connection unit installed to reciprocate within the housing unit and having a terminal connection portion to or from which an electric terminal is attached and detached,
wherein the terminal connection portion is variable so that the electric terminal is insertable when the terminal connection portion is separated from the housing ring and the electric terminal is fixed when the terminal connection portion is inserted into the housing ring together with the electric terminal inserted.

2. The electrical terminal connector of claim 1, wherein the terminal connection unit includes a hollow shaft having the terminal connection portion,
wherein the hollow shaft includes,
a hollow body; and
the terminal connection portion disposed by penetrating through the housing ring and extending in a radial direction while extending from an end of the hollow body,
the terminal connection portion is formed of a plurality of portions spaced apart from each other, and as the plurality of portions are separated from the housing ring, a distance between the plurality of portions gradually increases.

3. The electrical terminal connector of claim 2, wherein the terminal connection unit further includes an elastic member connecting the housing unit and the hollow shaft and applying elastic force to the hollow shaft so that the terminal connection portion moves back into the housing ring when the terminal connection portion is separated from the housing ring.

4. The electrical terminal connector of claim 3, wherein the terminal connection unit further includes,
a connecting pipe having one end into which an end of the hollow shaft is inserted and fastened, and the other end into which an electric cable is insertable; and
a support member provided with a support hole into which the other end of the connecting pipe is inserted and fastened,
wherein the support member is provided with a fixing groove in which the elastic member is fixed, and the hollow shaft is connected to the elastic member by the connecting pipe and the support member.

5. The electrical terminal connector of claim 4, wherein the hollow shaft and the connecting pipe are formed of a conductive material.

6. The electrical terminal connector of claim 1, wherein the housing unit includes,
a base member installed by penetrating through the heater cup and having a base hole;
a screw pipe installed in the base hole and having a pipe hole; and
the housing ring installed in the pipe hole.

7. The electrical terminal connector of claim 6, wherein the base member is provided with a base entrance portion connected to the base hole, and an internal space of the base entrance portion is tapered toward the base hole.

8. The electrical terminal connector of claim 1, wherein the housing unit includes,
a base body installed by penetrating through the heater cup and having a body hole;
a housing installed by penetrating through the body hole, having a housing hole, and having a housing groove provided on a side to have a space spaced apart from an inner surface of the body hole;
a snap ring disposed between a lower jaw of the base body and a lower jaw of the housing;
a screw pipe installed in the housing hole and having a pipe hole; and
the housing ring installed in the pipe hole.

9. The electrical terminal connector of claim 8, wherein the housing has a housing inlet connected to the housing hole, and an internal space of the housing inlet is tapered toward the housing hole.

10. A substrate support comprising:
a heating plate equipped with a heater and an electrical terminal connected to the heater;
a heater cup having a bottom portion with a support pin supporting the heating plate; and
an electrical terminal connector installed on the heater cup,
wherein the electrical terminal connector includes,
a housing unit installed by penetrating through the heater cup and having a housing ring; and
a terminal connection unit installed to reciprocate within the housing unit and having a terminal connection portion to or from which an electric terminal is attachable and detachable, and
the terminal connection portion has a variable structure, so that the electric terminal is insertable when the terminal connection portion is separated from the housing ring, and the electric terminal is fixed when the terminal connection portion is inserted into the housing ring together with the electric terminal inserted.

11. The substrate support of claim 10, wherein the terminal connection unit includes a hollow shaft having the terminal connection portion,
wherein the hollow shaft includes,
a hollow body disposed by penetrating through the housing ring; and
the terminal connection portion extending from an end of the hollow body and having a gradually expanded cross-sectional area, and
the terminal connection portion has a structure in which an interval between a plurality of portions spaced apart from each other increases away from the hollow body.

12. The substrate support of claim 11, wherein the terminal connection unit further includes an elastic member connecting the housing unit and the hollow shaft and providing elastic force to the hollow shaft so that the terminal connection portion moves back into the housing ring when the terminal connection portion is separated from the housing ring.

13. The substrate support of claim 12, wherein the terminal connection unit further includes,
a connecting pipe having one end into which an end of the hollow shaft is inserted and fastened and the other end into which an electric cable is insertable; and
a support member provided with a support hole into which the other end of the connecting pipe is inserted and fastened,
the support member is provided with a fixing groove in which the elastic member is fixed, and the hollow shaft is connected to the elastic member by the connecting pipe and the support member, and
the hollow shaft and the connecting pipe are formed of a conductive material.

14. The substrate support of claim 10, wherein the housing unit includes,
a base member installed by penetrating through a bottom portion of the heater cup and having a base hole;
a screw pipe installed in the base hole and having a pipe hole; and
the housing ring installed in the pipe hole,
wherein the base member is provided with a base entrance portion connected to the base hole, and an internal space of the base entrance portion is tapered toward the base hole.

15. The substrate support of claim 10, wherein the housing unit includes,
a base body installed by penetrating through a bottom portion of the heater cup and having a body hole therein;
a housing installed by penetrating through the body hole, having a housing hole therein, and having a housing groove provided on a side to have a space spaced apart from an inner surface of the body hole;
a snap ring disposed between a lower jaw of the base body and a lower jaw of the housing;
a screw pipe installed in the housing hole and having a pipe hole; and
the housing ring installed in the pipe hole,
wherein the housing has a housing inlet connected to the housing hole, and an internal space of the housing inlet is tapered toward the housing hole.

16. A substrate processing apparatus comprising:
a processing chamber including an upper body and a lower body to form a processing space therein;
a substrate support disposed in the processing space and supporting and heating a substrate; and
a substrate lifting unit including a lifting pin lifted and lowered while penetrating through the substrate support, and a pin driving member lifting and lowering the lifting pin,
wherein the substrate support includes,
a heating plate equipped with a heater and an electrical terminal connected to the heater;
a heater cup having a bottom portion with a support pin supporting the heating plate; and
an electrical terminal connector installed on the heater cup,
wherein the electrical terminal connector includes,
a housing unit installed by penetrating through the heater cup and having a housing ring; and
a terminal connection unit installed to reciprocate within the housing unit and having a terminal connection portion to and from which an electric terminal is attachable and detachable, and
the terminal connection portion has a variable structure, so that the electric terminal is insertable when the terminal connection portion is separated from the housing ring, and the electric terminal is fixed when the terminal connection portion is inserted into the housing ring together with the electric terminal inserted.

17. The substrate processing apparatus of claim 16,
wherein the terminal connection unit includes a hollow shaft having the terminal connection portion,
wherein the hollow shaft includes,
a hollow body disposed by penetrating through the housing ring; and
the terminal connection portion having a cross-sectional area gradually expanding while extending from an end of the hollow body, and
the terminal connection portion has a structure in which a distance between a plurality of portions spaced apart from each other increases away from the hollow body.

18. The substrate processing apparatus of claim 17, wherein the terminal connection unit further includes an elastic member connecting the housing unit and the hollow shaft and providing elastic force to the hollow shaft so that the terminal connection portion moves back into the housing ring when the terminal connection portion is separated from the housing ring.

19. The substrate processing apparatus of claim 18,
wherein the terminal connection unit further includes, a connecting pipe having one end into which an end of the hollow shaft is inserted and fastened and the other end into which an electric cable is insertable; and
a support member provided with a support hole into which the other end of the connecting pipe is inserted and fastened,
wherein the support member is provided with a fixing groove to which the elastic member is fixed, and the hollow shaft is connected to the elastic member by the connecting pipe and the support member, and
the hollow shaft and the connecting pipe are formed of a conductive material.

20. The substrate processing apparatus of claim 16, wherein the housing unit includes,
a base body installed by penetrating through a bottom portion of the heater cup and having a body hole therein;
a housing installed by penetrating through the body hole, having a housing hole therein, and having a housing groove provided on a side to have a space spaced apart from an inner surface of the body hole;
a snap ring disposed between a lower jaw of the base body and a lower jaw of the housing;
a screw pipe installed in the housing hole and having a pipe hole; and
the housing ring installed in the pipe hole, and
the housing has a housing inlet connected to the housing hole, and an internal space of the housing inlet is tapered toward the housing hole.
